(19) United States
(12) Patent Application Publication
(10) Pub. No.: US 2026/0026400 A1
(43) Pub. Date: Jan. 22, 2026

(54) HIGH DENSITY DEVICE PACKAGE AND PACKAGING TECHNIQUE THEREOF

(71) Applicant: Analog Devices, Inc., Wilmington, MA (US)

(72) Inventor: Vikas Paduvalli, San Jose, CA (US)

(21) Appl. No.: 18/780,328

(22) Filed: Jul. 22, 2024

(51) Int. Cl. H01L 25/18; H01L 23/29; H01L 23/31; H01L 23/42; H01L 23/498; H01L 23/66; H01L 25/065

(52) U.S. Cl. CPC H01L 25/18; H01L 23/293; H01L 23/3128; H01L 23/42; H01L 23/49816; H01L 23/66; H01L 25/0652; H01L 2223/6616; H01L 2223/6672

(57) ABSTRACT

A high-density integrated device package may include two or more primary device dies arranged along a first plane, an inductor comprising an inductor core and an inductor coil, the inductor being fixedly connected to at least one of the primary device dies, and a dielectric substrate arranged along a second plane which is substantially perpendicular to the first plane. The integrated device package further includes a secondary device die (e.g., a power IC) electrically connected to the dielectric substrate such that an orientation of the secondary device die is substantially perpendicular to that of the two or more primary device dies, wherein the dielectric substrate is fixedly connected to the inductor core, and wherein the dielectric substrate is electrically connected to at least one of the primary device dies by an edge connector.

### BACKGROUND

### Technical Field

The present application relates to the field of integrated device packaging, particularly systems and methods of device packaging offering a high density of active and passive devices.

### Description of the Related Art

Integrated device packages have a number of applications in consumer electronics, aeronautics, and many other industries. However, with existing packages, it can be challenging to provide adequate heat dissipation due to the high density of devices. Accordingly, there remains a continuing need for improved high density device packages with novel thermal interfaces.

### SUMMARY

In one embodiment, an integrated device package can include: a primary device die arranged along a first plane; an energy storage device connected to the primary device die; a substrate arranged along a second plane which is non-parallel to the first plane; and a secondary device die electrically connected to a first side of the substrate such that an orientation of the secondary device die is non-parallel to that of the primary device die. A second side of the substrate can be connected to the energy storage device such that the substrate is between the secondary device die and the energy storage device.

In some embodiments, the energy storage element comprises an inductor comprising an inductor core and an inductor coil. In some embodiments, the integrated device package is a ball grid array (BGA) package, a land grid array (LGA) package, or a package having copper pillars as interconnects. In some embodiments, the substrate is a printed circuit board (PCB). In some embodiments, the primary device die, the secondary device die, and the energy storage device collectively form a driver-MOSFET (DrMOS) power stage. In some embodiments, the integrated device package can include at least two primary device dies including the primary device die, the at least two primary device dies spaced apart by at least one slot. In some embodiments, the substrate is electrically connected to the primary device die by an edge connector, the edge connector comprising a conductive pad located at an edge of the dielectric substrate and extending into the at least one slot. In some embodiments, the inductor comprises a leg extending into the slot. In some embodiments, the inductor is fixedly connected to the primary device die by an adhesive or epoxy resin. In some embodiments, each of the primary device die and the energy storage element comprises a planarized surface. In some embodiments, the primary device die comprises a semiconductor device at least partially embedded in an encapsulant. In some embodiments, the integrated device package is encapsulated in an insulating overmold. In some embodiments, the insulating overmold is partially removed to provide clearance around a thermal interface of the secondary device die and a thermal interface of the inductor on two or more sides of the integrated device package. In some embodiments, the insulating overmold is partially removed by grinding or laser ablation. In some embodiments, a heat sink or heat exchanger is formed over the two or more sides of the integrated device package to contact the thermal interface of the secondary device die and thermal interface of the inductor.

In another embodiment, a method of manufacturing an integrated device package is disclosed. The method can include: mounting a secondary device die to a first side of a substrate; connecting an inductor to a second side of the substrate such that the secondary device die and the inductor are electrically connected; and mounting a leg of the inductor between two or more primary device dies. The secondary device die and the inductor can be oriented to provide clearance around thermal interfaces on at least two sides of the integrated device package.

In some embodiments, the method further comprises mounting an edge connector of the substrate in a slot formed between the two or more primary device dies. In some embodiments, the substrate is electrically connected to at least one of the primary device dies by the edge connector. In some embodiments, the two or more primary device dies, the secondary device die, and the inductor collectively form a driver-MOSFET (DrMOS) power stage. In some embodiments, the method further comprises fixedly connecting the inductor to a surface of at least one of the primary device dies by an adhesive or epoxy resin. In some embodiments, the method can include encapsulating the two or more primary device dies, the secondary device die, the inductor, and the substrate in an insulating overmold. In some embodiments, the method can include removing an excess portion of the insulating overmold to maintain the clearance around the thermal interfaces on two or more sides of the integrated device package. In some embodiments, the method can include forming a heat sink or heat exchanger over the two or more sides of the integrated device package to contact the thermal interfaces of the secondary device die and the inductor.

In another embodiment, a semiconductor device package can include: a first semiconductor device die; a second semiconductor device die; and an inductor. The second semiconductor device die can be oriented on a substrate non-parallel to the first semiconductor device die. The second semiconductor device die can be electrically connected to the first semiconductor device die by an edge connector of the substrate. The inductor can be provided over the first semiconductor device die to provide passive cooling to the first semiconductor device die. A thermal interface of the second semiconductor device die and a thermal interface of the inductor can be exposed on respective side surfaces of the semiconductor device package.

In some embodiments, the edge connector extends between a slot disposed between the first semiconductor device die and a third semiconductor device die. In some embodiments, the first semiconductor device die comprises a semiconductor device at least partially embedded in an encapsulating material.

In another embodiment, an integrated device package can include: a carrier arranged along a first plane; an electronic device connected to the carrier; a substrate arranged along a second plane which is non-parallel to the first plane; and a secondary device die electrically connected to a first side of the substrate such that an orientation of the secondary device die is non-parallel to that of the carrier. A second side of the substrate is connected to the electronic device such that the substrate is between the secondary device die and the electronic device.

In some embodiments, the carrier comprises a primary integrated device die and the electronic device comprises an energy storage device.

### BRIEF DESCRIPTION OF THE DRAWINGS

FIG. 1A and FIG. 1B are schematic representations of a high density integrated device package according to a first embodiment.

FIG. 2A and FIG. 2B are schematic representations of a power stage assembly of the high density integrated device package taken along the lines 2A-2A and 2B-2B, respectively.

FIG. 3 is a schematic representation of a high density integrated device package according to a second embodiment.

FIG. 4 is a schematic representation of a high density integrated device package according to a third embodiment.

FIG. 5A and FIG. 5B are schematic representations of a vertical PCB of the high density integrated device package of FIG. 4 taken along the lines 5A-5A and 5B-5B, respectively.

### DETAILED DESCRIPTION OF THE PREFERRED EMBODIMENT

Integrated device packages can include a package substrate and one or more integrated device dies mounted to the package substrate. In high frequency applications, the die(s) can be configured to operate at high frequencies, e.g., at frequencies of 300 kHz or greater, 400 kHz or greater, 0.6 GHz or greater, 10 GHz or greater, or 50 GHz or greater. For example, the die(s) can operate at frequencies in a range of 300 kHz to 10 MHz, or in a range of 300 kHz to 20 MHz. For example, high frequency integrated device dies can operate at one or more operational frequencies in a range of 0.6 GHz to 150 GHz, or in a range of 0.6 GHz to 120 GHz. The die(s) are typically mounted to a laminate substrate (such as a printed circuit board, or PCB) by way of solder balls or any other technique known to those skilled in the art.

Certain devices, particularly devices with a high continuous current draw (e.g., current draw of 1 A or greater, 10 A or greater, or 100 A or greater), present a challenge to the miniaturization of high density device packages due to the difficulty of heat dissipation. Such devices may be referred to generally as power integrated circuits (ICs), and can include driver-MOSFET (DrMOS) power stages which combine a power metal-oxide semiconductor field effect transistor (MOSFET) with one or more gate drivers and passive devices (e.g., inductors or capacitors). Resistive heating in power ICs can be significant, giving way to contemporary high density package architectures that offer a direct thermal interface to these heat-generating components. Examples of such designs include through-mold slotted via component-on-package (TMSV-CoP) devices and certain high density multi-phase power block devices. Examples of such TMSV-CoP devices are shown throughout U.S. Pat. No. 10,497,635, the entire contents of which are incorporated by reference herein in their entirety and for all purposes.

Accordingly, in various embodiments disclosed herein, a high density integrated device package can utilize a three-dimensional structure to provide a thermal interface on two or more sides of the package for improved cooling. In various embodiments, an assembly combining an energy storage device (such as a passive component (e.g., an inductor)) and a vertical substrate (e.g., a vertically-oriented printed circuit board (PCB)) with one or more power ICs can be mounted over a plurality of low-power device packages. The assembly provides a thermal interface for the power IC and passive component(s) on two or more sides of the device package (e.g., a top surface and a side wall). In various embodiments, the high density integrated device package can have a clearance on two or more sides of the package to provide passive cooling. In certain embodiments, the clearance can be an area free of encapsulating material or other structures. In other embodiments, the high density integrated device package may be provided with a heat sink or heat exchanger to assist in cooling the assembly. One or more heat sinks can be mounted adjacent to or substantially connected to each thermal interface on a corresponding side of the device package.

As will be discussed herein, passive device(s) can be electrically connected to the power IC (such as in the case of a DrMOS power stage) while providing structural support for the vertical PCB and assembly. Any of the illustrated embodiments can be enclosed in an encapsulating material or overmold. In various embodiments, the encapsulating material can comprise an organic encapsulant (e.g., epoxy resin) or an inorganic encapsulant. The high density integrated device package is preferably a ball grid array (BGA) package, but can alternatively be configured as a land grid array (LGA) package or any other type of package known to those skilled in the art.

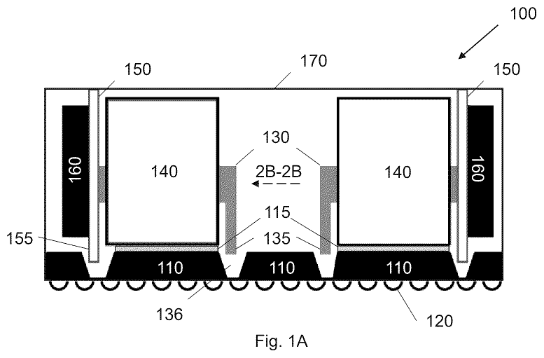

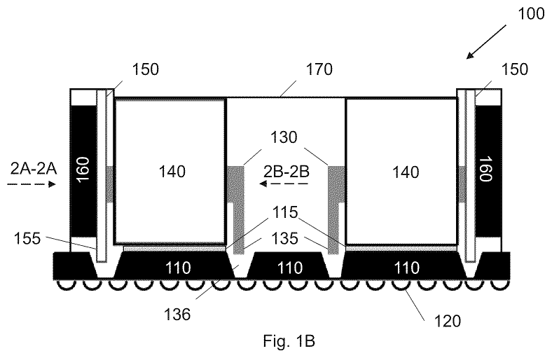

Referring initially to FIGS. 1A-1B, an example of a high density integrated device package 100 is shown. The example integrated device package 100 of FIGS. 1A-1B includes a pair of DrMOS power stage assemblies. Although a pair of DrMOS power stage assemblies are shown, it should be appreciated that any number of DrMOS power stage assemblies (e.g., three, four, five, ten, twenty, etc.) can be used. The power stage assemblies provide an upper thermal interface for a pair of inductors 140 on a top surface of the device package 100 and side thermal interfaces for a pair of power ICs 160 on opposite side walls of the integrated device package 100. Although energy storage devices (e.g., a type of electronic device) including inductors 140 are shown in FIGS. 1A-1B, in other embodiments, other types of energy storage devices (e.g., capacitors) can be used in any of the disclosed embodiments. The high density integrated device package 100 utilizes two or more sides of the package (e.g., the upper thermal interface and side thermal interfaces) for more efficient heat dissipation, allowing for increased device density and/or higher continuous current draw without requiring an enlarged footprint of the device package 100. Moreover, the integrated device package 100 offers improved cooling of both power ICs 160 and passive devices (e.g., the inductors 140), overcoming a tradeoff suffered by other high density integrated device packages.

A base layer of the high density integrated device package 100 can include a plurality of primary device dies 110 comprising two or more semiconductor devices (e.g., low-power Ics) and/or passive devices arranged along a first plane. The device dies 110 can be encapsulated in a molding compound in various embodiments (such that in some embodiments the device dies 110 include semiconductor devices embedded in an encapsulant). The primary device dies 110 can serve as a carrier to which the energy storage devices (e.g., an electronic device such as an inductor, capacitor, transformer, etc.) are connected. The primary device dies 110 can be devices having a relatively low current draw (e.g., less than 1 A continuous current draw), and which would not benefit significantly from a direct thermal interface on the exterior of the device package 100. The primary device dies 110 can comprise any suitable type of device die, such as a processor die or a radio frequency (RF) device dic. In various embodiments, the dies 110 can additionally or alternatively include passive devices such as decoupling capacitors, which can advantageously enable the positioning of the decoupling capacitors closer to the board. One or more of the primary device dies 110 can be configured to operate at high frequencies, e.g., one or more operational frequencies in a range of 0.6 GHz to 250 GHz, or in some embodiments, in a range of 0.6 GHz to 120 GHz. The plurality of device dies 110 can be formed of any suitable type of semiconductor material. For example, each die 110 can comprise silicon, silicon germanium, gallium arsenide, gallium nitride, or any other suitable semiconductor material. Each die 110 can be provided with or without backside vias.

Bond pads (not shown) of the primary device dies 110 can be mounted to a surface of a system board (e.g., a printed circuit board, a bismaleimide triazine (BT) substrate, etc.) or other substrate by a plurality of conductive interconnects 120 (e.g., solder balls). In certain embodiments, the high density integrated device package 100 can be a BGA package, an LGA package, or a package having copper pillars as interconnects. The system board may be a part of an electronic device (e.g., a computing device), or can form the basis of a module which combines several integrated device packages in a common housing (e.g., an RF module).

One or more power stage assemblies (e.g., DrMOS power stage assemblies) are provided above the plurality of primary device dies 110. Each power stage assembly can include an inductor or another passive device. For example, in FIG. 1A, the inductor of each power stage assembly comprises an inductor core 130, formed of, for example, ferrite or powdered iron (e.g., a composite material), and an inductor coil 140 comprising a plurality of conductive windings wrapped around the inductor core. Although an inductor is shown in FIG. 1A, in other embodiments, the power stage assembly can include one or more capacitors, field effect transistors (FET), gate-driving FETs, or transformers The inductor coil 140 has a top surface and a bottom surface. In certain embodiments, the inductor coil 140 can have substantially planar top and/or bottom surfaces to facilitate heat transfer from one or more of the primary device dies 110 to an exterior surface of the integrated device package 100 by way of the inductor. FIGS. 1A-1B illustrate a pair of thermally conductive pads 115, such as adhesive pads, which connect a corresponding bottom surface of each inductor coil 140 to one of the plurality of primary device dies 110. In other embodiments, a portion of epoxy or resin may be used to mount the inductor coil 140 to one of the plurality of primary device dies 110. Each additional inductor increases the thermal mass of the integrated device package 100, behaving as an intermediate heat sink for the primary device dies 110 in addition to any heat sink or cooling device on the exterior surface(s) of the integrated device package 100.

The inductor core 130 further includes a vertical leg 135, which is a narrow end of the solid metal core which extends into a slot 136 or valley formed between two adjacent ones of the plurality of primary device dies 110. The end of the vertical leg 135 can be electrically connected to (e.g., soldered to) a substrate exposed by the slot 136. The vertical leg 135 offers structural stability to the entire power stage assembly, and may be permanently fixed in place once an insulating overmold 170 is formed over the integrated device package 100. In certain embodiments, the vertical leg 135 may be electrically connected to the base layer and one or more of the plurality of primary device dies 110, such as in the case of a circuit ground.

Each power stage assembly further comprises a dielectric substrate with embedded conductive traces and terminals (referred to herein as a vertical PCB 150) and one or more power ICs 160 (i.e., secondary device dies) mounted to the PCB 150, both of which are substantially vertical in relation to the base layer of the integrated device package 100 and primary device dies 110. The one or more power ICs 160 are mounted to (e.g., soldered to terminals on) a first side of the vertical PCB 150 along a second plane and non-parallel to (e.g., substantially perpendicular to) the first plane, whereas a second side of the PCB 150 is fixedly and electrically connected to an end of the inductor core 130 opposite from the vertical leg 135. For example, in the illustrated embodiments, each of the power ICs 160, the primary device dies 110, and the vertical PCB 150 includes a major lateral surface that is transverse to the respective thicknesses of the power ICs 160, primary device dies 110, and the vertical PCB 150. As used herein, the orientations of the vertical PCB 150 and power ICs 160 parallel to the respective major lateral surface can be non-parallel to (e.g., substantially perpendicular to) the major lateral surface of the primary device die 110. In various embodiments, a conductive adhesive can connect the second side of the PCB 150 to the inductor. In certain embodiments, both sides of the vertical PCB 150 may include power ICs 160 or other secondary semiconductor devices.

Those skilled in the art will also appreciate that the vertical orientation of the vertical PCB 150 can cause the one or more power ICs 160 to abut corresponding exterior side surface(s) of the integrated device package 100. Unlike conventional device packages, which may have a single thermal interface on a top surface of the package (and therefore be constrained by the density of heat-generating power ICs), the high-density integrated device package 100 makes efficient use of the top and side exterior surfaces to provide additional thermal interfaces for better cooling.

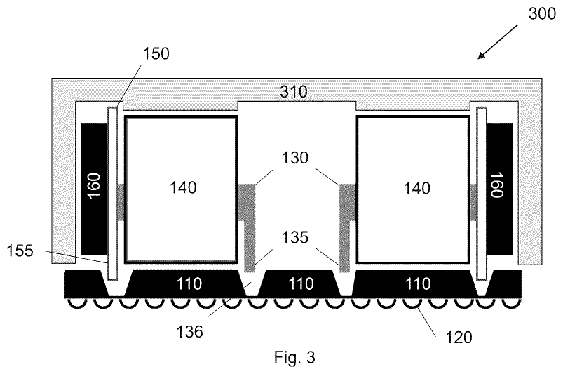

As discussed below with reference to FIG. 3, a thermally-conductive heat sink or heat shroud can be formed over an entire exterior of the integrated device package 100 to provide cooling for the power ICs 160 (directly via the side exterior surfaces) and the plurality of primary device dies 110 (indirectly via the inductor coil(s) 140 and top exterior surface). Because the power ICs 160 have a comparably higher current draw and are generally the main sources of heat in the integrated device package 100, their vertical orientation also serves to isolate the primary device dies 110 from high-temperature regions at the periphery of the package 100 while providing direct access to these regions for cooling devices (e.g., a heat sink, heat slug, or active cooling devices).

When an insulating overmold 170 is applied over the power stage assemblies and the base layer of the integrated device package 100, the overmold 170 may cover the top and side thermal interfaces, reducing the capacity for heat dissipation by the integrated device package 100. For certain applications, direct access to the thermal interfaces is not required, and the overmold may be ground down to a substantially rectangular profile, as shown by FIG. 1A. Alternatively, FIG. 1B illustrates the integrated device package 100 after excess portions of insulating overmold 170 have been further removed from the top and side thermal interfaces (such as by grinding or laser ablation), offering better heat dissipation. Different methods of removing the overmold 170 may be combined to avoid damaging the fragile power IC(s) 160 on either side of the package 100, such as by grinding the overmold down to a substantially rectangular profile (FIG. 1A) and further removing the excess portions of overmold by laser ablation (FIG. 1B) to expose the top and side thermal interfaces. The profile of the overmold 170 can therefore be refined in preparation for fixedly attaching a heat sink to the device package 100, as discussed below with reference to FIG. 3.

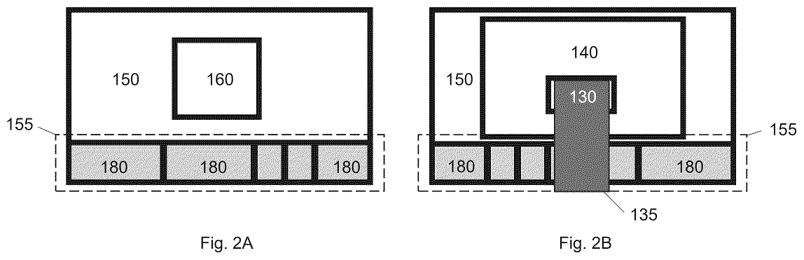

Referring now to FIGS. 2A-2B, elevational views of one power stage assembly of the high-density integrated device package 100 are shown. FIG. 2A is taken along the line 2A-2A, a first side of the power stage assembly, illustrating one power IC 160 mounted to the first side of the vertical PCB 150. FIG. 2B is taken along the line 2B-2B, an opposite side of the power stage assembly, illustrating the inductor core 130 mounted to the second side of the vertical PCB 150. FIG. 2B further illustrates the vertical leg 135 of the inductor core 130, which extends from a center of the inductor coil 140 beyond a lower portion 155 of the vertical PCB 150. In certain embodiments, the vertical leg 135 can be aligned with an edge of the lower portion 155 of the vertical PCB 150 from the perspective of FIG. 2B. In other embodiments, the vertical leg 135 may not extend fully to the edge of the lower portion 155, but still overlaps at least partially with the lower portion 155 of the vertical PCB 150. When the vertical leg 135 is not aligned precisely with the edge of the lower portion 155, the vertical leg 135 and the lower portion 155 preferably have similar lengths to facilitate connecting the vertical PCB 150 and the inductor core 130 to the base layer of the device package 100, as in FIGS. 1A-1B.

The vertical PCB 150 includes a plurality of edge connectors 180 provided within the lower portion 155. In the example of FIGS. 2A-2B, the edge connectors 180 are conductive pads (e.g., solder pads), but may include any combination of electrical connectors (e.g., pads, pins, zero-insertion-force connectors and the like) known to those skilled in the art. The edge connectors 180 can be electrically connected to the power IC(s) 160 and/or a passive component (e.g., the inductor core 130 or inductor coil 140) of the power stage assembly by a plurality of conductive traces or interconnects (not shown) of the vertical PCB 150. In some embodiments, the edge connectors 180 can each be of a similar size. In other embodiments, a surface area of specific edge connectors can be relatively wider than others, such as for power delivery to the power stage assembly. Certain edge connectors may be left electrically disconnected, and serve to provide additional support for the vertical PCB 150. The lower portion 155 of the vertical PCB 150 may also be keyed to prevent the edge connectors 180 from being mounted to the base layer improperly. In some embodiments, the edge connectors 180 can be disposed in or adjacent to the slot 136 and can connect to a substrate or other device connected to the dies 110.

In certain embodiments, as shown in FIG. 3, a heat sink 310 is formed over the exterior of the integrated device package 100 (e.g., contacting the top and side thermal interfaces) to provide cooling for the power ICs 160 and the plurality of primary device dies 110. In FIG. 3, the top surface of the integrated device package 100 is in contact with a bottom (inner) surface of the heat sink 310. The heat sink 310 can be a metal layer of uniform thickness which is wrapped over the integrated device package 100 once excess portions of insulating overmold have been removed. Alternatively, the heat sink 310 can have an increased thickness in areas which directly contact heat-generating components. In yet another embodiment, the heat sink 310 may be part of a heat exchanger configured to apply cooling directly to one or more high-density integrated device packages 100.

The thermally-conductive heat sink 310 may be a solid metal layer (e.g., copper or aluminum), or can comprise layers of metals or metal alloys. In certain embodiments, a top (outer) surface of the heat sink 310 may include a plurality of fins to facilitate passive cooling of the integrated device package 100. Installation of the heat sink 310 may further include applying a thermally conductive material (e.g., a conductive pad or conductive liquid) to the thermal interfaces of the integrated device package 100 before the heat sink 310 is mounted, further improving cooling efficiency at the thermal interfaces. In some embodiments, the heat sink 310 can contact or be adhered to (by a thermally conductive adhesive) one or more of the power ICs 160 and inductor coil 140. In some embodiments, the heat sink 310 can contact or be adhered to (by a thermally conductive adhesive) portions of an encapsulant in which the power ICs 160 and inductor coil 140.

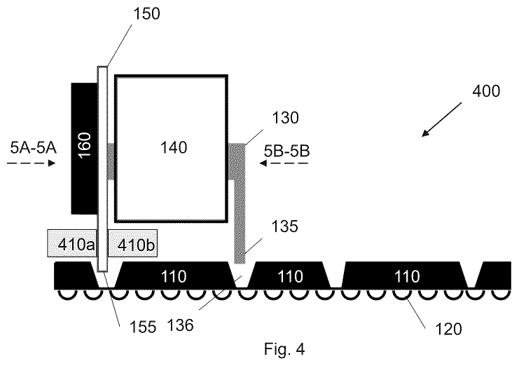

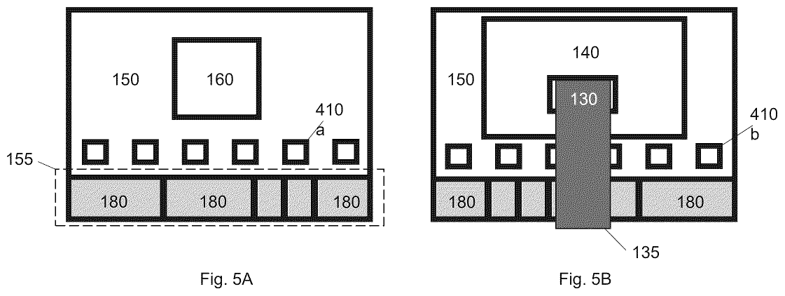

FIG. 4 illustrates an example of a high-density integrated device package 400 which includes a plurality of interconnects 410 to provide additional stability to the vertical PCB 150. FIG. 5A and FIG. 5B are clevational views of one power stage assembly of the high-density integrated device package 400.

Interconnects (sometimes referred to as vertical interconnects) are traditionally used to couple adjacent layers of a PCB or to stack multiple PCBs in a single assembly. In the high-density integrated device package 400, a first plurality of interconnects 410a and a second plurality of interconnects 410b are provided on opposite sides of the vertical PCB 150 for additional mounting stability atop the plurality of primary device dies 110. The interconnects 410 are solid projections (e.g., copper or aluminum blocks) which extend orthogonal to the vertical PCB 150 and lie substantially flat against a top surface of one or more of the primary device dies 110 in the base layer. For example, in an embodiment wherein the inductor coil 140 does not have a flat bottom surface for mounting to a BGA package 110, the first plurality of interconnects 410a and a second plurality of interconnects 410b can be provided to stabilize the power stage assembly. As illustrated by FIGS. 5A and 5B, the plurality of interconnects 410 may be aligned in a row on each side of the vertical PCB 150 just above the lower portion 155 of the PCB 150. This allows the weight of the vertical PCB 150 and power assembly to be supported by the plurality of interconnects 410, while the edge connectors 180 remain in contact with the base layer between the plurality of primary device dies 110. As shown in FIG. 4, the vertical PCB 150 and the vertical leg 135 of the inductor core 130 may be elongated to provide clearance for the plurality of interconnects 410 underneath the power stage assembly.

### Applications

Some of the embodiments described above have provided examples in connection with mobile devices. However, the principles and advantages of the embodiments can be used for any other systems or apparatus including, but not limited to, mobile phones, tablets, base stations, network access points, customer-premises equipment (CPE), laptops, and wearable electronics.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An integrated device package, comprising:
a primary device die arranged along a first plane;
an energy storage device connected to the primary device die;
a substrate arranged along a second plane which is non-parallel to the first plane; and
a secondary device die electrically connected to a first side of the substrate such that an orientation of the secondary device die is non-parallel to that of the primary device die;
wherein a second side of the substrate is connected to the energy storage device such that the substrate is between the secondary device die and the energy storage device.

2. The integrated device package of claim 1, wherein the energy storage element comprises an inductor comprising an inductor core and an inductor coil.

3. The integrated device package of claim 1, wherein the integrated device package is a ball grid array (BGA) package, a land grid array (LGA) package, or a package having copper pillars as interconnects.

4. The integrated device package of claim 1, wherein the substrate is a printed circuit board (PCB).

5. The integrated device package of claim 1, wherein the primary device die, the secondary device die, and the energy storage device collectively form a driver-MOSFET (DrMOS) power stage.

6. The integrated device package of claim 1, further comprising at least two primary device dies including the primary device die, the at least two primary device dies spaced apart by at least one slot.

7. The integrated device package of claim 6, wherein the substrate is electrically connected to the primary device die by an edge connector, the edge connector comprising a conductive pad located at an edge of the dielectric substrate and extending into the at least one slot.

8. The integrated device package of claim 6, wherein the inductor comprises a leg extending into the slot.

9. The integrated device package of claim 8, wherein the inductor is fixedly connected to the primary device die by an adhesive or epoxy resin.

10. The integrated device package of claim 1, wherein each of the primary device die and the energy storage element comprises a planarized surface.

11. The integrated device package of claim 1, wherein the primary device die comprises a semiconductor device at least partially embedded in an encapsulant.

12. The integrated device package of claim 1, wherein the integrated device package is encapsulated in an insulating overmold.

13. The integrated device package of claim 12, wherein the insulating overmold is partially removed to provide clearance around a thermal interface of the secondary device die and a thermal interface of the inductor on two or more sides of the integrated device package.

14. The integrated device package of claim 13, wherein the insulating overmold is partially removed by grinding or laser ablation.

15. The integrated device package of claim 13, wherein a heat sink or heat exchanger is formed over the two or more sides of the integrated device package to contact the thermal interface of the secondary device die and thermal interface of the inductor.

16. A method of manufacturing an integrated device package, the method comprising:
mounting a secondary device die to a first side of a substrate;
connecting an inductor to a second side of the substrate such that the secondary device die and the inductor are electrically connected; and
mounting a leg of the inductor between two or more primary device dies;
wherein the secondary device die and the inductor are oriented to provide clearance around thermal interfaces on at least two sides of the integrated device package.

17. The method of manufacturing an integrated device package according to claim 16, wherein the method further comprises mounting an edge connector of the substrate in a slot formed between the two or more primary device dies.

18. The method of manufacturing an integrated device package according to claim 17, wherein the substrate is electrically connected to at least one of the primary device dies by the edge connector.

19. The method of manufacturing an integrated device package according to claim 18, wherein the two or more primary device dies, the secondary device die, and the inductor collectively form a driver-MOSFET (DrMOS) power stage.

20. The method of manufacturing an integrated device package according to claim 16, wherein the method further comprises fixedly connecting the inductor to a surface of at least one of the primary device dies by an adhesive or epoxy resin.

21. The method of manufacturing an integrated device package according to claim 16, further comprising encapsulating the two or more primary device dies, the secondary device die, the inductor, and the substrate in an insulating overmold.

22. The method of manufacturing an integrated device package according to claim 21, further comprising removing an excess portion of the insulating overmold to maintain the clearance around the thermal interfaces on two or more sides of the integrated device package.

23. The method of manufacturing an integrated device package according to claim 22, further comprising forming a heat sink or heat exchanger over the two or more sides of the integrated device package to contact the thermal interfaces of the secondary device die and the inductor.

24. A semiconductor device package, comprising:
a first semiconductor device die;
a second semiconductor device die; and
an inductor;
wherein the second semiconductor device die is oriented on a substrate non-parallel to the first semiconductor device die;
wherein the second semiconductor device die is electrically connected to the first semiconductor device die by an edge connector of the substrate;
wherein the inductor is provided over the first semiconductor device die to provide passive cooling to the first semiconductor device die; and
wherein a thermal interface of the second semiconductor device die and a thermal interface of the inductor are exposed on respective side surfaces of the semiconductor device package.

25. The semiconductor device package of claim 24, wherein the edge connector extends between a slot disposed between the first semiconductor device die and a third semiconductor device die.

26. The semiconductor device package of claim 24, where the first semiconductor device die comprises a semiconductor device at least partially embedded in an encapsulating material.

27. An integrated device package, comprising:
a carrier arranged along a first plane;
an electronic device connected to the carrier;
a substrate arranged along a second plane which is non-parallel to the first plane; and
a secondary device die electrically connected to a first side of the substrate such that an orientation of the secondary device die is non-parallel to that of the carrier;
wherein a second side of the substrate is connected to the electronic device such that the substrate is between the secondary device die and the electronic device.

28. The integrated device package of claim 27, wherein the carrier comprises a primary integrated device die and the electronic device comprises an energy storage device.
